(19) United States
(12) Patent Application Publication
(10) Pub. No.: US 2008/0095986 A1
(43) Pub. Date: Apr. 24, 2008

(54) Multi-Layer Body with Differently Microstructured Areas Provided with an Electroconductive Coating

(76) Inventors: Andreas Schilling, Hagendorn (ZG) (CH); Wayne Robert Tompkin, Baden (CH)

Correspondence Address: Charles R Hoffmann;Hoffmann & Baron, 6900 Jericho Turnpike, Syosset, NY, 11791, US

(21) Appl. No.: 11/661,484

(22) PCT Filed: Aug. 24, 2005
(86) PCT No.: PCT/EP05/09137

§ 371 Date: May 21, 2007

(30) Foreign Application Priority Data
Aug. 30, 2004 (DE) 102004042111.0

(51) Int. Cl. B32B 27/00; C23C 16/06

(52) U.S. Cl. 428/167; 427/585

(57) ABSTRACT

Described is a multi-layer body (11, 12) having a replication lacquer layer (22). A first relief structure (25, 125, 65) is shaped into the replication lacquer layer (22) in a first region of the multi-layer body in a plane defined by co-ordinate axes x and y and an electrically conductive coating (23l, 23n, 123n) of a constant surface density is applied to the replication lacquer layer (22) in the first region of the multi-layer body (11, 12) and in an adjacent second region of the multi-layer body (11, 12). The first relief structure (25, 125, 65) is a structure with a high depth-to-width ratio in respect of the individual structure elements, in particular with a depth-to-width ratio>2. At least one perpendicular or almost perpendicular flank extends over the entire or almost the entire depth of the relief structure, the flank in that way reducing or suppressing electrical conductivity of the coating.

The invention concerns a multi-layer body with a replication lacquer layer in which a relief structure is formed and which is provided with an electrically conductive coating.

Multi-layer bodies in the form of film elements are used in many areas, for example as security elements for producing optical effects. They are also used as part of an electrical circuit arrangement or they themselves form an electrical circuit arrangement, for example a switching circuit. Such circuits are used for example as so-called RFID tags (RFID=radio frequency identification), that is to say article labels for the identification of articles by means of radio frequencies. The term RF identification is generally used to denote contactless RF communication between a transponder which is associated with an object or a person and a reading device. In that case the transponder has for example an antenna which is part of a resonance circuit and/or is connected to a semiconductor chip.

For such purposes of use, conductive structures have to be produced on or in the film element, with such structures being of very small dimensions. Various process steps have to be carried out for that purpose, which are labor-intensive, environmentally polluting or quality-reducing such as for example etching electrically conductive layers. Due to the etching operation for example a semiconductor layer disposed under the conductive structures can be contaminated, in which respect just very small amounts of foreign atoms can be a significant source of interference.

Because of the layer structure of circuits, generally a plurality of cycles of such process steps are required so that further expenditure has to be incurred for production in accurate register relationship.

Now, the object of the invention is to avoid the specified disadvantages and to provide multi-layer bodies with structured, electrically conducting coatings, which can be manufactured at low cost, with a high level of precision and with a high level of resolution.

The object of the invention is attained by a multi-layer body having a replication lacquer layer, wherein a first relief structure is shaped into the replication lacquer layer in a plane defined by co-ordinate axes x and y in a first region of the multi-layer body and an electrically conductive coating of constant surface density is applied to the replication lacquer layer in the first region of the multi-layer body and in an adjacent second region of the multi-layer body. The first relief structure is a structure with a high depth-to-width ratio of the individual structure elements, in particular with a depth-to-width ratio>2, and has at least one perpendicular or almost perpendicular flank extending over the entire or a substantial part of the depth of the relief structure, wherein at the perpendicular or almost perpendicular flank of the first relief structure there are regions at which the conductive coating applied to the first relief structure is not deposited or is deposited only in such a small layer thickness that the electrical conductivity of the coating in the region of the flanks is significantly reduced.

The object of the invention is further attained by a process for the production of a multi-layer body, wherein in the process a first relief structure is shaped into a replication lacquer layer of the multi-layer body in a first region of the multi-layer body and an electrically conductive coating of constant surface density is applied to the replication lacquer layer in the first region of the multi-layer body and in an adjacent second region of the multi-layer body. The first relief structure is in the form of a structure with a high depth-to-width ratio of the individual structure elements, in particular with a depth-to-width ratio>2, and is shaped with at least one perpendicular or almost perpendicular flank, wherein at the flanks of the first relief structure there are regions at which the conductive coating applied to the first relief structure is not deposited or is deposited only in such a small layer thickness that the electrical conductivity of the coating in the region of the flanks is significantly reduced.

The fact that the first relief structure is produced with such a high depth-to-width ratio and with at least one perpendicular or almost perpendicular flank means that at the flanks of the relief structure there are regions at which the conductive coating applied to the relief structure is not deposited or is deposited only in such a small layer thickness that the electrical conductivity of the coating in the region of the flanks is significantly reduced or the coating is even entirely interrupted there. The high level of resolution which can be achieved is of particular advantage in that respect, that is to say, it is possible to produce very fine conduction structures, such as cannot be embodied by an optical exposure process with subsequent etching. It is further possible by means of the invention to precisely adjust the surface resistance of conduction regions and to encode items of information which can be read out in that way into security elements.

The dimensionless depth-to-width ratio is a characterizing feature in regard to the characterization of structures, in particular microstructures. It is preferably used to describe periodic structures, for example of a sawtooth-shaped configuration. Here, the spacing between the highest and the lowest successive points of the structure is identified as the depth, that is to say this involves the spacing between a “peak” and a “trough”. The spacing between two adjacent highest points, that is to say between two “peaks”, is referred to as the width (period). Now, the higher the depth-to-width ratio, the correspondingly steeper are the “peak flanks”. The description model can also be applied to non-periodic structures. For example this can involve discretely distributed line-shaped regions which are only in the form of a “trough”, wherein the spacing between two “troughs” is greater by a multiple than the depth of the “troughs”. Upon formal application of the above-specified definition, the depth-to-width ratio calculated in that way would be approximately zero and would not reflect the characteristic physical condition. Therefore, in the case of discretely arranged structures which are formed substantially only from a “trough”, the depth of the “trough” is to be related to the width of the “trough”.

In spite of the above-mentioned advantages the production process according to the invention is inexpensive for it avoids complicated and expensive process steps for structuring of conductor tracks.

It is provided that the first relief structure is in the form of a function of the co-ordinates x and/or y, which periodically varies the depth of the first relief structure in the x-direction and/or in the y-direction. In that respect preferred functions are those which provide at least one perpendicular flank or side. Sawtooth functions and rectangular functions are preferred. Perpendicular flanks with sharp edges are formed in that way so that the conductive coating is interrupted, with a defined contour, along the edges. In that way the coating on the first relief structure is electrically non-conducting in a direction perpendicular to the edges or involves a very high level of electrical resistance.

The thickness t of the coating which is deposited on an inclined flank that is inclined at an angle α relative to the horizontal is given by the relationship
t=t₀·cos α
In that relationship to is the thickness of the coating deposited on a horizontal surface. In that respect the thickness t₀ is to be adjusted in dependence on the coating material in such a way that the inclined flanks are not “smudged”, that is to say no coating material or only a layer thickness which is markedly reduced in relation to planar surfaces is deposited there. With an increasing thickness t₀, deposits can possibly also be formed on a perpendicular or almost perpendicular flank for example if particles of the coating material do not move on the common trajectory of the particle stream. The optimum value can preferably be ascertained by a series of experiments. The optimum value of the thickness t₀ is directed to the production at the flank of the first relief structure, of regions at which the conductive coating applied to the first relief structure is not deposited or is deposited only such a small layer thickness that the electrical conductivity of the coating is significantly reduced in the region of the flank.

The thickness t₀ of unstructured regions should be less than 500 nm, preferably less than 50 nm. The optimum thickness t₀ can advantageously be determined by testing, whereby it is also possible to take account of the influence of the coating material on the electrical and other properties of the coating material.

If the relief structure to be coated has a high depth-to-width ratio, the effect of forming regions on the perpendicular or almost perpendicular flanks of the first relief structure, at which the conductive coating applied to the first relief structure is not deposited or is deposited only in such a small layer thickness that the electrical conductivity of the coating is significantly reduced in the region of the flanks is advantageously enhanced. It can preferably be provided that the depth-to-width ratio of the relief structure is >2.

As tests have shown, the angle α of the flanks can differ in magnitude from the perpendicular by about 10°, without casting doubt on the described effect.

The thickness t of the coating on the flanks can be adjusted by selection of the angle α. In that respect, the angle α may also be the gradient angle of a curve portion which can be determined by the first derivative of the curve.

If the first relief structure is in the form of a function of a coordinate, the relief structure is of a particularly simple configuration. In particular the first relief structure can be a diffractive structure with small grating periods, for example in a range of between 50 nm and 10 μm. Such a relief structure can be a linear diffraction grating.

It can be provided that a linear polarizer is formed in that way, preferably with a period length of between 100 nm and 800 nm. Preferably the coating can be of a thickness t₀<10 nm. By virtue of the high possible resolution of the first relief structure, the configuration of the linear polarizer is not limited to the configuration for polarization in an oscillation plane. Rather, it can be provided that in that way regions in mutually juxtaposed relationship can be afforded, with differing polarization directions, in which respect the regions can be in the form of information carriers. By way of example, the regions can form a machine-readable bar code or can be in the form of alphanumeric characters or an image or graphic representation. Those regions can be visible in polarized light, for example if they are so oriented that their polarization plane is oriented perpendicularly to that of the light which is radiated thereonto or therethrough, whereby they stand out dark from the background. It is also possible to provide a “decryption” film which, upon illumination with unpolarized light, in conjunction with the above-described structure, causes items of concealed information to emerge.

It can also be provided however that the first relief structure is in the form of a function of two co-ordinates, wherein the perpendicular flanks provided are in the form of curves which are closed in themselves. The electrically conductivity of the applied coating is interrupted in all directions in that way. It can preferably be provided that the closed curves are in the form of circles, ellipses, squares, rectangles and rhombuses.

It can also be provided however that the closed curve follows the contour of an adjacent second region in which a second relief structure is shaped. It is preferably provided that the second relief structure is of a planar configuration. In that way, the electrically conducting coating applied to the second relief structure is in the form of an electrical conductor of a full thickness t₀. Because an electrically conductive second region which is contoured in any desired way can be surrounded by the first electrically non-conducting region, it is possible in that way to produce mutually electrically insulated conductor paths of any geometry with a high level of accuracy and resolution by means of a common coating step.

Further advantageous configurations are set forth in the appendant claims.

It is preferably provided that the electrically conductive coating is in the form of a metal layer, preferably formed from a good electrical conductor such as aluminum, copper, silver or gold. It can however also be provided that the coating is in the form of transparent conductive material, for example an indium-tin oxide layer (ITO) which is preferred by virtue of its transparency for forming “invisible” conductor tracks, as are used for example in displays. Electrode layers for photovoltaics can be produced on the basis of the same principle.

It can also be provided however that a metallic coating is so thin that it appears transparent, being formed for example with a thickness of between 1 nm and 100 nm, preferably a thickness of between 5 nm and 30 nm. That can be advantageous if “invisible” conductor tracks for low currents, as are provided for example for LCD displays, are produced in that way.

Particularly when producing conductor tracks, it is important that the coating is certain to be interrupted at the edges of the conductor tracks. For that purpose the preferred layer thickness t₀ can be in the range of between 5 nm and 50 nm. As described hereinafter the conductivity of those thin conductor tracks can be increased if required by galvanization.

Preferably the multi-layer body is in the form of a film element, for example a transfer film, in particular a hot stamping film, in the form of a laminated film or in the form of a sticker film. In that case the film element can also be formed by the applied transfer layer of a transfer film. It can also be provided however that the multi-layer body includes a rigid substrate layer, for example a thin glass layer.

The electrically conductive coating can be applied with the processes known from the production of security elements, for example by sputtering, electron beam vapor deposit or thermal vapor deposit with resistance heating. Those processes are distinguished in that the coating is applied by spraying with a constant density in relation to surface area, with respect to a plane defined by co-ordinate axes x and y. Preferably the atoms or molecules impinge on the plane, that is to say the surface to be coated, at approximately the same angle.

It can advantageous be provided that the atoms or molecules impinge perpendicularly on to the surface to be coated so that they are not deposited on perpendicular or almost perpendicular flanks.

These therefore do not involve a coating process in which the atoms or molecules are deposited in non-directed fashion, whereby they are deposited independently of the flank inclination, in a layer of approximately equal layer thickness. Non-directed deposit can for example involve deposition out of the gaseous phase.

It is preferably provided that the relief structures are shaped by means of UV replication in the replication lacquer layer.

The use of the structures according to the invention and the process according to the invention is possible in many different ways and is always particularly advantageous when a diffractive film element is to carry an electrical circuit arrangement or is itself part of an electrical circuit.

It is further possible for electrode layers of semiconductor components of polymer electronics to be structured by means of the invention. The invention makes it possible to achieve high levels of resolution. It is further provided that conductor tracks of polymer circuits or other electrical components, for example coils and capacitors for RFID tags (RFID=radio frequency identification) are produced in the described fashion. It is particularly advantageous in that respect that the invention affords an inexpensive production technology with a low waste reject rate for the production of structures of that kind. Because of the fine structuring which can be achieved with the process according to the invention, it is possible in that way for the limit frequency of those semiconductor components to be further markedly increased.

It can be provided that the conductive coating is galvanically strengthened and in that way either a particularly good conductive surface layer is applied or the thickness of the deposited layer is increased in order to reduce the electrical resistance. The above-indicated deposition processes are preferably suitable for the application of thin layers. As has been found, the relief structure is not altered in the galvanization operation, that is to say electrically non-conductive regions are not covered over.

It is possible with the process according to the invention to produce further components such as linear polarizers particularly inexpensively in the form of film products.

The invention is described by way of example hereinafter by means of a number of embodiments with reference to the accompanying drawings in which:

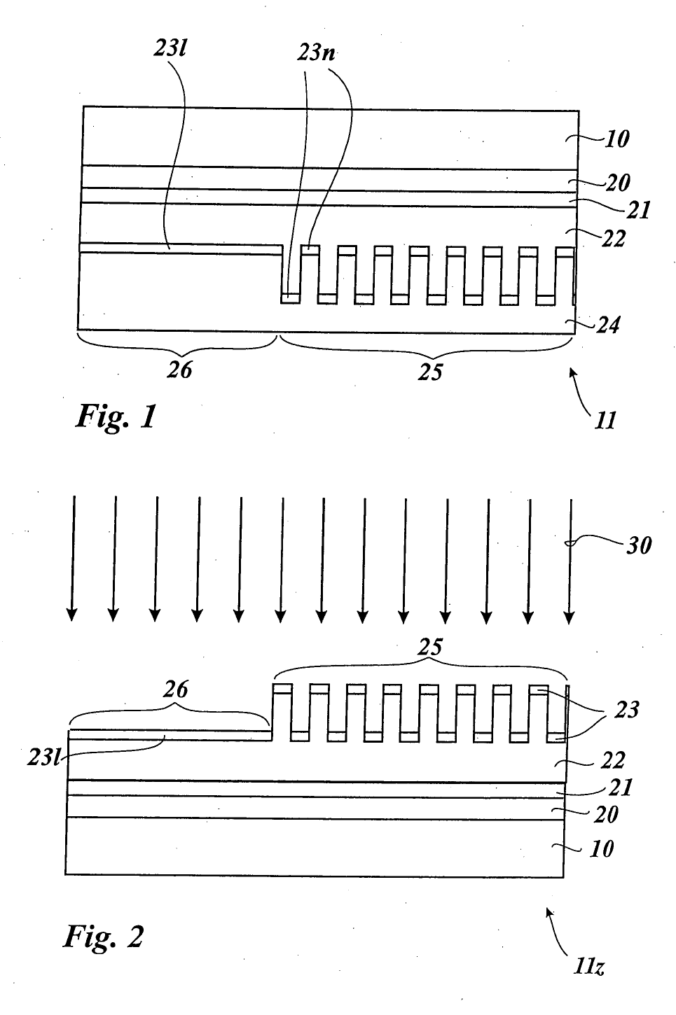

FIG. 1 shows a diagrammatic sectional view of a first embodiment of a multi-layer body according to the invention in the form of a film element,

FIG. 2 is a diagrammatic view of the coating of the film element in FIG. 1 with a metal layer,

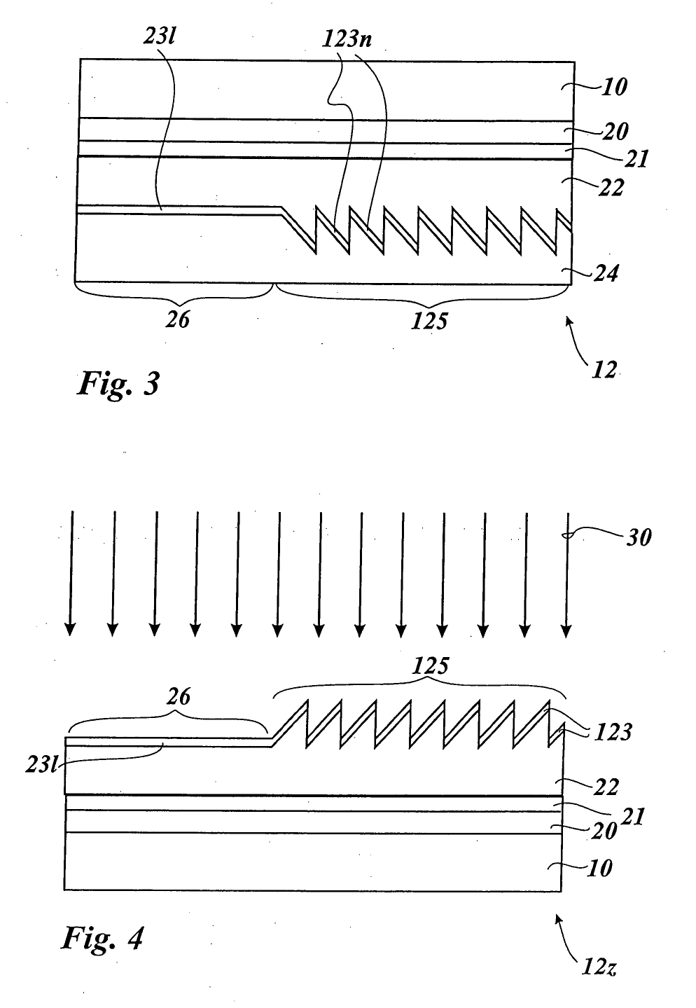

FIG. 3 shows a diagrammatic sectional view of a second embodiment of a multi-layer body according to the invention in the form of a film element,

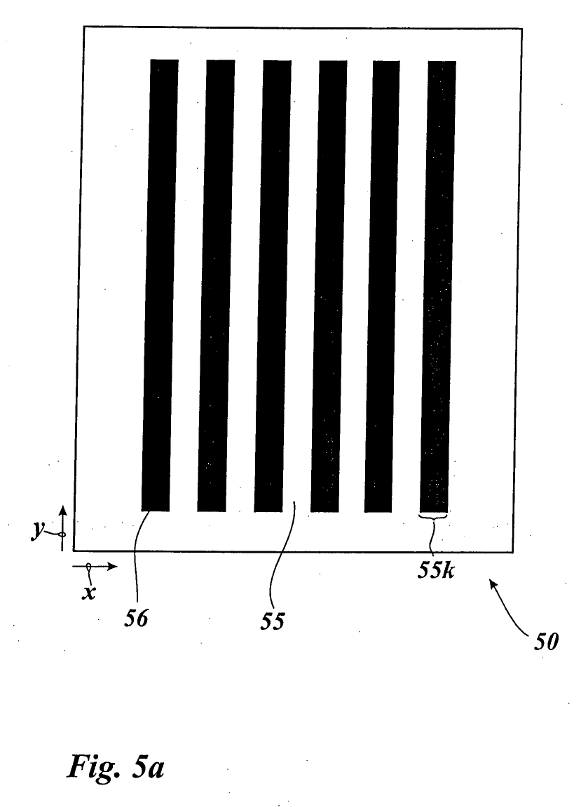

FIG. 4 is a diagrammatic view of the coating of the film element in FIG. 3 with a metal layer,

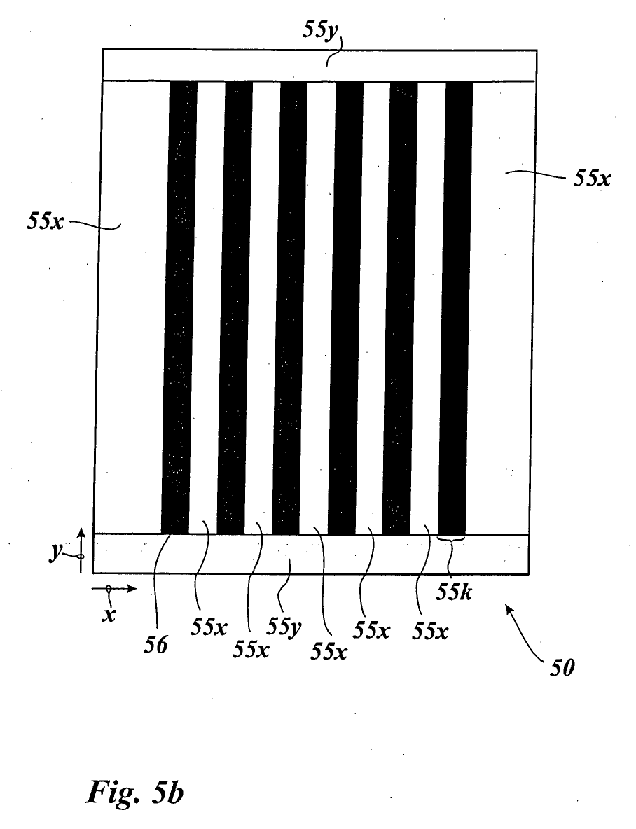

FIG. 5 shows a diagrammatic plan view of an embodiment of a multi-layer body in the form of a film element with a one-dimensional relief structure,

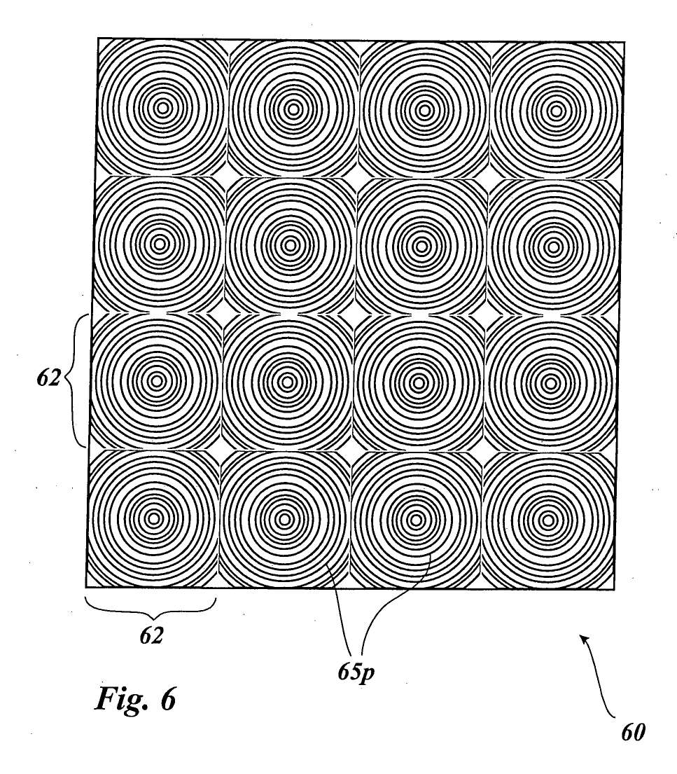

FIG. 6 shows a diagrammatic plan view of an embodiment of a multi-layer body in the form of a film element with a two-dimensional relief structure, and

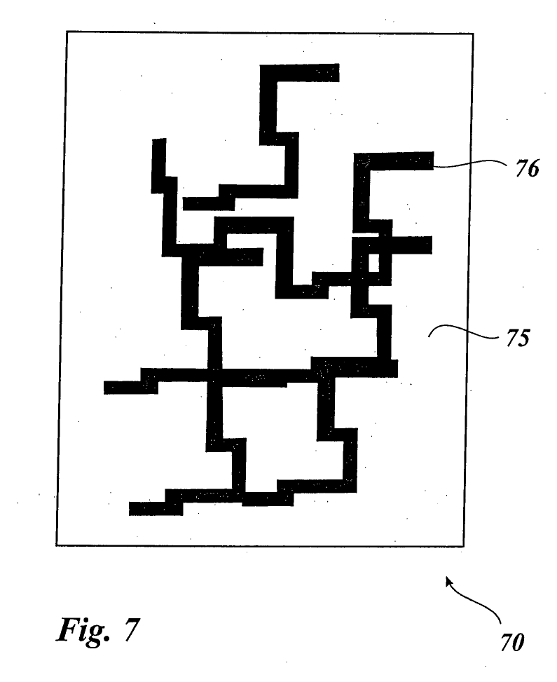

FIG. 7 shows a diagrammatic plan view of an embodiment of a multi-layer body in the form of a film element with an electrical conductor track.

FIG. 1 shows a multi-layer body in the form of a film element, referred to hereinafter as the film element 11. The film element 11 comprises a carrier film 10, a release layer 20, a protective lacquer layer 21, a replication lacquer layer 22 with relief structures 25 and 26, coatings 23l, 23n arranged on the relief structures 25 and 26 and an adhesive layer 24. The relief structure 26 is in the form of a planar relief structure. The relief structure 25 is a structure with a high width-to-depth ratio and thus that relief structure has an effective surface area which is a multiple higher than usual relief structures which are shaped for example for the production of optical effects in security elements. The relief structure 25 is of a meander-shaped configuration with flanks perpendicular to the surface of the planar relief structure 26. In the illustrated embodiment it extends in a coordinate direction. In that way the coating 23n which is applied in area relationship is arranged only on the portions of the relief structure 25, that are parallel to the surface of the planar relief structure 26, that is to say, the coating is a coating which is interrupted in a co-ordinate direction. Such a relief structure which is interrupted in a co-ordinate direction is referred to hereinafter as a one-dimensional relief structure. As shown in FIG. 1, the interruption is continuous throughout. In contrast the coating 23l arranged on the planar relief structure 26 is of a closed configuration.

In the illustrated embodiment, different effects can be produced by virtue of the selection of the material and by the configuration of the relief structure. If for example the coatings 23l, 23n are in the form of metal layers, the coating 23n is a non-conducting metal layer because it is interrupted throughout at the perpendicular flanks of the relief structure. In contrast the metal layer applied to the planar relief structure 26 is electrically conducting for it is not interrupted. The coating 23n can be applied for example by sputtering, that is to say by a coating process in which particles of approximately the same coating direction impinge on the relief structure. Therefore no or significantly few particles impinge at the perpendicular flanks which are disposed parallel to the coating direction, so that there the coating 23n is interrupted or has a significantly higher resistance per unit of surface area, which for example is higher by at least a factor of 10, preferably higher by a factor 1000, than the resistance per unit of surface area of the conductive coating 23l outside the perpendicular flanks.

Such a coating process is further distinguished in that it applies the coating with a constant density in relation to surface area, with respect to a plane defined by co-ordinate axes x and y, wherein advantageously the coating direction can be oriented parallel to the flanks of the relief structure, which are perpendicular or oriented approximately perpendicularly to the plane.

The high depth-to-width ratio of the relief structure 25, which is advantageously >2, has a substantial share in the described effect of the provision of the thickness of the coating, which is dependent on the flank angle. On the one hand, the high depth-to-width ratio provides for steep flanks, while on the other hand random deposit of particles which deviate from the set coating direction is made more difficult thereby.

A further influencing factor is the thickness of the coating which is produced on the planar relief structure 26. As tests have shown, the above-described effect occurs for thicknesses<500 nm.

Preferably the thickness of the conductive coating which is produced on the planar relief structure 26 can be <50 nm in order to obtain perpendicular or approximately perpendicular flanks in the relief structure 26, on which no conductive coating is formed at least in region-wise fashion.

It can be provided that such a layer is to be transparent, for example of a thickness of about 10 nm. In that way it is possible to form conductor tracks which visually do not cover the structures disposed therebeneath, for example LCD display elements.

The film element 11 is a stamping or embossing film, in particular a hot stamping film. It is however also possible for the film element 11 to be in the form of a laminating film or sticker film or in the form of a carrier for a circuit, in particular a polymer circuit.

The carrier layer 10 comprises for example a PET or POPP film of a layer thickness of between 10 μm and 50 μm, preferably of a thickness of between 19 μm and 23 μm. The release layer 20 and the protective lacquer layer 21 are then applied to the carrier film by means of an intaglio printing screen cylinder. In that case the release and protective lacquer layers 20 and 21 are preferably of a thickness of between 0.2 and 1.2 μm. It would also be possible to dispense with those layers.

The replication lacquer layer 22 is then applied.

The replication lacquer layer 22 preferably comprises a radiation-crosslinkable replication lacquer. Preferably a UV replication process is used for shaping the relief structures 25 and 26 in the replication lacquer layer 22. In that case a UV-hardenable lacquer is used as the replication lacquer. In that situation, introduction of the relief structures 25 and 26 into the UV-crosslinkable replication lacquer layer is effected for example by UV irradiation when shaping the relief structure in the lacquer layer when it is still soft or fluid, or by partial irradiation and hardening of the UV-crosslinkable lacquer layer. In that case, instead of a UV-crosslinkable lacquer it is also possible to use another radiation-crosslinkable lacquer.

Furthermore it is also possible for the replication lacquer layer 22 to comprise a transparent thermoplastic material. A relief structure or a plurality of relief structures, for example the relief structures 25 and 26, is or are then stamped in the replication lacquer layer 22 by means of a stamping tool.

The thickness which is to be selected for the replication lacquer layer 22 is determined by the profile depth selected for the relief structure 25. It is necessary to ensure that the replication lacquer layer 22 is of a sufficient depth to permit the relief structures 25 and 26 to be shaped. Preferably in that case the replication lacquer layer 22 is of a thickness of between 0.1 and 10 μm.

By way of example the replication lacquer layer 22 is applied over the full surface area involved to the protective lacquer layer 21 with an application weight of 2.2 g/m² prior to drying, by means of a line raster intaglio printing cylinder. In that case a lacquer of the following composition is selected as the replication lacquer:

| Component | Proportion by weight |
|---|---|
| High-molecular PMMA resin | 2000 |
| Silicone alkyd oil-free | 300 |
| Non-ionic wetting agent | 50 |
| Low-viscosity nitrocellulose | 12000 |
| Toluene | 2000 |
| Diacetone alcohol | 2500 |

The replication lacquer layer 22 is then dried in a drying passage at a temperature of between 100 and 120° C.

The relief structures 25 and 26 are then stamped into the replication lacquer layer 22 for example by means of a die comprising nickel, at about 130° C. For stamping the relief structures 25 and 26 into the replication lacquer layer, the die is preferably electrically heated. Before the die is lifted off the replication lacquer layer 22 after the stamping operation the die can in that case be cooled down again. After the relief structures 25 and 26 have been stamped into the replication lacquer layer 22 the replication lacquer of the replication lacquer layer 22 hardens by cross-linking or in some other fashion.

It is further also possible for the relief structures 25 and 26 to be introduced into the replication lacquer layer 22 by an ablation process.

In that respect the relief structures 25 and 26 involve relief structures which are coated with the coatings 23l, 23n in a common coating process, for example sputtering.

As can be seen from FIG. 2 the coating direction for deposition of the coatings 23l, 23n is oriented perpendicularly to the surface of the planar relief structure 16. The orientation direction is identified by arrows 30 in FIG. 2. In that respect the coating apparatus is designed in such a way that the material is deposited on the relief structures 25 and 26 with a constant surface area density so that as a result of that process step the surface area density of the coatings 23l, 23n on the relief structures 25 and 26 is equal and constant. In that way therefore no precautions whatsoever are necessary in order for example to make the conductivity of coatings 23l, 23n different and/or to produce the geometry of the coatings 23l, 23n. In that respect it is particularly advantageous that structuring of the coatings 23l, 23n can be effected in accurate register relationship in one production step and that, because of the microstructuring of the relief structures, particularly high levels of resolution are achieved, as are necessary for example when producing circuits.

The adhesive layer 24 is then applied to the coatings 23l, 23n. The adhesive layer 24 is preferably a layer comprising a thermally activatable adhesive. Depending on the respective use of the security element 11 however it is also possible to dispense with the adhesive layer 24.

FIG. 3 now shows a second embodiment of a multi-layer body in the form of a film element 12 with a one-dimensional relief structure, this arrangement differing from the above-described embodiment only in regard to the configuration of the relief structure. Identical elements are therefore denoted by the same references. Instead of the meander-shaped relief structure 25 in FIG. 1, the film element 12 is designed with a sawtooth-shaped relief structure 125. The relief structure 125 has a first flank arranged perpendicularly to the surface of the planar relief structure 26 and a second flank arranged in angular relationship with the first flank. That configuration provides that the coating 23n is arranged only on the second flanks of the relief structure 125, that is to say the coating is of an interrupted configuration.

FIG. 4 now shows the coating of the relief structures 125 and 26 in FIG. 3 with coatings 123n and 23l. As already described hereinbefore with reference to FIG. 2, the coatings 123n and 23l are applied to the relief structures 125 and 26 respectively in a common production step, for example by sputtering. As can be clearly seen from FIG. 4, in this case the coating 123n is produced on the inclined second flanks of the relief structure 125, of a smaller thickness than on the relief structure 26 arranged perpendicularly to the application direction. Because the coating 123n is interrupted by the perpendicular first flanks of the relief structure 125, which are not coated with material, for example a metal layer applied in that way is electrically non-conducting.

FIG. 5a now shows a diagrammatic plan view of a multi-layer body in the form of a film element 50 with a one-dimensional relief structure, which in the illustrated embodiment is coated with metal. In this case an electrically non-conducting region 55 with a one-dimensional relief structure with a high depth-to-width ratio is provided, as shown in FIGS. 1 and 3 (references 25 and 125 respectively), in which conducting planar regions 56 which are shown black in FIG. 5 are enclosed. These involve conductor tracks which connect together electrical components which are not shown here.

Although the electrically non-conducting region 55 is interrupted by non-coated perpendicular flanks only in the co-ordinate direction identified by x, and is locally electrically short-circuited in portions 55k in which it adjoins electrically conducting regions 56 in the y-direction, it is overall of an electrical conductivity which is orders of magnitude less than the conductivity of the regions 56.

FIG. 5b now shows how it is possible to avoid the above-described local short-circuit by the conducting regions 56. For that purpose the region 55 is subdivided into regions 55x and regions 55y, the relief structure of which varies in the x-direction and in the y-direction respectively. Such an arrangement can be provided when the conducting regions 56 are not arranged in mutually parallel relationship or are of a curved configuration.

It can however also be provided that the regions 56 applied with the process according to the invention are galvanically reinforced. Because the regions 55, 55x and 55y are electrically non-conducting, no metal is deposited there in the galvanization operation. Therefore, no additional precautions have to be taken in order to galvanically reinforce only the conducting regions 56. In that way, the conducting planar regions 56 are in the form of conductor tracks with a lower level of specific resistance, than prior to the galvanization operation. It is therefore possible to dispense with the formation of the region 55 (see FIG. 5a) in the form of differently oriented regions 55x and 55y (see FIG. 5b) because the electrical conductivity of the regions 56 is significantly greater in comparison with the electrical conductivity of the region 55.

The regions 56 shown in FIGS. 5a and 5b can be transparent, for example if a very thin metal layer of an order of magnitude of 10 nm is applied there, differing according to the respective kind of metal involved.

FIG. 6 now shows a diagrammatic plan view of a multi-layer body in the form of a film element 60 with raster screen elements 62 which have relief structures 65 with a high depth-to-width ratio and perpendicular flanks which form profile curves 65p that are closed in themselves. In the illustrated embodiment the profile curves are in the form of circles and rhombuses. The film element 60 is coated with a metal layer (not shown) which is non-conducting because of the relief structures 65. This involves two-dimensional relief structures which avoid the above-discussed disadvantage of a possible short-circuit by electrically conducting regions. As can be clearly seen from FIG. 6 the relief structures 65 are formed from concentrically arranged circles which are inscribed in the square raster elements 62. In that way, segments of circles are formed in the corner regions of the raster elements 62. In that fashion, the segments of a circle in a corner region form rhombic profile curves, with the segments of the circles of the three further raster elements 62 which are adjacent in that corner region.

It can be provided that the raster elements 62 are produced in the same configuration and of the same size, that is to say in the form of isosceles triangles, squares or hexagons. It can also be provided that the raster elements 62 are of an irregular configuration, that is to say they fill up the area of the film element 60 with raster elements 62 of differing configurations and sizes. The only important consideration is that the perpendicular flanks of the relief structure 65 form closed curves.

FIG. 7 now shows a multi-layer body which is coated with metal, in the form of a film element 70 with a structured conductor 76 surrounded by regions 75 which are provided with relief structures with a high depth-to-width ratio. The relief structures can be in the form of one-dimensional relief structures (see FIG. 5) or two-dimensional relief structures (see FIG. 6) with a high depth-to-width ratio. A preferred arrangement is a two-dimensional relief structure and a depth-to-width ratio>2.

The film element 70 can be in the form of part of a micro-electronic circuit, for example part of a polymer circuit in the form of a film system. In that respect the circuit can be transparent, as described hereinbefore (see FIG. 5).

It can be provided in relationship to such a use that one or more portions of the structured conductor 76 are formed with a relief structure with a high depth-to-width ratio so that the electrical conductivity of the conductor 76 is reduced in such a portion. It is possible in that way for example to form electrical resistors in the conductor 76.

1. A multi-layer body having a replication lacquer layer, wherein a first relief structure is shaped into the replication lacquer layer in a plane defined by co-ordinate axes x and y in a first region of the multi-layer body and an electrically conductive coating of constant surface density is applied to the replication lacquer layer in the first region of the multi-layer body and in an adjacent second region of the multi-layer body, and wherein
the first relief structure is a structure with a depth-to-width ratio of the individual structure elements, greater than 2:1 and has at least one substantially perpendicular flank extending substantially over the entire depth of the relief structure, wherein at the flank of the first relief structure there are regions at which the conductive coating applied to the first relief structure is not deposited or is deposited only in such a small layer thickness that the electrical conductivity of the coating in the region of the flank is significantly reduced.

2. A multi-layer body as set forth in claim 1, wherein the coating is a metal layer.

3. A multi-layer body as set forth in claim 1, wherein the coating comprises a transparent conductive material.

4. A multi-layer body as set forth in claim 1, wherein the first relief structure is in the form of a function of the co-ordinates x and/or y, which periodically varies the depth of the first relief structure in the x-direction and/or in the y-direction.

5. A multi-layer body as set forth in claim 4, wherein the first relief structure is substantially in the form of a rectangular function of the co-ordinates x or y, which periodically varies the depth of the first relief structure in the x-direction or in the y-direction.

6. A multi-layer body as set forth in claim 4, wherein the first relief structure is in the form of a sawtooth function of the co-ordinates x or y, which periodically varies the depth of the first relief structure in the x-direction or in the y-direction.

7. A multi-layer body as set forth in claim 4, wherein the first relief structure is in the form of a rectangular function or a sawtooth function of the co-ordinates x and y, which periodically varies depth of the first relief structure in the x-direction and in the y-direction, wherein the perpendicular flanks of those functions form convex curves which are closed in themselves.

8. A multi-layer body as set forth in claim 1, wherein a second relief structure is shaped into replication lacquer layer in the adjacent second region.

9. A multi-layer body as set forth in claim 8, wherein second relief structure is substantially planar or is formed with a low depth-to-width ratio.

10. A multi-layer body as set forth in claim 8, wherein the second relief structure is in the form of a function of the co-ordinates x and/or y, which varies the depth of the relief structure the x-direction and/or in the y-direction, wherein that function is formed without a perpendicular flank.

11. A multi-layer body as set forth in claim 1, wherein the coating applied to the second relief structure is transparent.

12. A multi-layer body as set forth in claim 11, wherein the transparent coating is in the form of a metal layer of a thickness of between 1 nm and 100 nm.

13. A multi-layer body as set forth in claim 1, wherein the multi-layer film body is a transfer film.

14. A circuit formed from polymer structures, with a multi-layer body as set forth in claim 1.

15. A linear polarizer with a multi-layer body as set forth in claim 1.

16. A security element with regions in the form of a linear polarizer as set forth in claim 15, wherein the regions are in the form of an information carrier.

17. A security document with a multi-layer body as set forth in claim 1.

18. A process for the production of a multi-layer body wherein in the process a first relief structure is shaped into a replication lacquer layer of the multi-layer body in a first region of the multi-layer body and an electrically conductive coating of constant surface density is applied to the replication lacquer layer in the first region of the multi-layer body and in an adjacent second region of the multi-layer body, and wherein
the first relief structure is in the form of a structure with a depth-to-width ratio of the individual structure elements greater than 2:1, and is shaped with at least one substantially perpendicular flank, wherein at the flank of the first relief structure there are regions at which the conductive coating applied to the first relief structure is not deposited or is deposited only in such a small layer thickness that the electrical conductivity of the coating in the region of the flank is significantly reduced.

19. A process as set forth in claim 18, wherein the coating is applied to the replication lacquer layer by sputtering.

20. A process as set forth in claim 19, wherein the coating is applied to the replication lacquer layer by electron beam vapor deposition.

21. A process as set forth in claim 20, wherein the coating is applied to the replication lacquer layer by thermal vapor deposition with resistance heating.

22. A process as set forth in claim 18, wherein the coating is galvanically reinforced.

23. A process as set forth in claim 18, wherein the relief structures are shaped in the replication lacquer layer by means of UV replication.
